(19) United States
(12) Patent Application Publication
(10) Pub. No.: US 2015/0124514 A1
(43) Pub. Date: May 7, 2015

(54) Lifetime of Ferroelectric Devices

(71) Applicant: PURDUE RESEARCH FOUNDATION, West Lafayette, IN (US)

(72) Inventors: Muhammad Ashraful Alam, West Lafayette, IN (US); Muhammad Masuduzzaman, West Lafayette, IN (US)

(73) Assignee: PURDUE RESEARCH FOUNDATION, West Lafayette, IN (US)

(21) Appl. No.: 14/533,897

(22) Filed: Nov. 5, 2014

Related U.S. Application Data
(60) Provisional application No. 61/900,022, filed on Nov. 5, 2013.

(51) Int. Cl. G11C 11/22

(52) U.S. Cl. CPC G11C 11/225
USPC 365/145

(57) ABSTRACT

A method and apparatus for increasing the lifetime of ferroelectric devices is presented. The method includes applying a waveform to the input pulse to increase the rise or fall time of the pulse. The waveform may comprise a ramp, a step, or combinations of both. The waveform may be symmetrical with respect to the rising and falling edges of the pulses. A temperature control device may also be operatively connected to increase the temperature of the device to increase lifetime. In other embodiments, a resistance may be operatively connected in series with the ferroelectric device to increase lifetime.

### RELATED APPLICATIONS

The present application claims the benefit of U.S. provisional application Ser. No. 61/900,022, filed Nov. 5, 2013, the contents of which are hereby incorporated by reference in its entirety.

### TECHNICAL FIELD

The present application relates to microelectronic devices, and particularly to ferroelectric devices.

### BACKGROUND

Ferroelectric devices such as ferroelectric memories (FeRAM) are often operated in AC switching configurations. Where normal dielectrics have a single potential well, and hence one equilibrium state, ferroelectrics have a double-well configuration with two stable energy states. This permits such devices to serve as memories. In an example of a Barium Titanate (BaTiO₃) ferroelectric, the Ti atom is central to a cubic structure with two energy pockets. The Ti atom can move between the energy pockets under the influence of an applied electric field corresponding to a drive waveform. However, if too much energy is applied by the electric field, the Ti and the neighboring oxygen bonds are stretched too much and can break, or other damage can be caused to the structure. This can stochastically happen even below the breaking energy, as energy from phonons can assist such damage. Such damage is accelerated in AC switching configurations as the FeRAMs are switched back and forth between the equilibrium states, and correspondingly, the Ti atoms gain kinetic energy during switching (becoming a “hot atom”). The damage accumulates over time, and eventually the ferroelectric device breaks down. With larger biases, lifetime decreases exponentially, because the difference between the maximum kinetic energy of the hot atoms and the bond-breaking energy decreases; this quantity relates to the speed of defect formation. There is, therefore, a need of ways of increasing the lifetime of ferroelectric devices such as FeRAMs.

Reference is made to U.S. Pat. No. 4,873,664, which is incorporated herein by reference in its entirety.

### SUMMARY

According to one embodiment, a method of operating a ferroelectric device is disclosed, comprising receiving a command to operate the ferroelectric device, and in response to the received command, applying a selected waveform to the ferroelectric device, the selected waveform having a non-zero rise time. The waveform may comprise a ramp function, a step function, or any function to increase the transition time of the waveform pulses.

According to another embodiment, a method of operating a ferroelectric device is disclosed, comprising receiving a command to operate the ferroelectric device, controlling the temperature of the ferroelectric device to increase the temperature of the ferroelectric device above a preselected temperature, and in response to the received command, applying a selected waveform to the ferroelectric device.

According to another embodiment, a ferroelectric device is disclosed, comprising a ferroelectric element, a resistive element operatively connected in series with the ferroelectric element, and a processor configured to apply a waveform across the series combination of the ferroelectric element and the resistive element.

According to another embodiment, a ferroelectric device is disclosed, comprising a ferroelectric element, and a processor configured to apply a waveform across the ferroelectric element. The waveform may comprise a ramp function, a step function, or any function to increase the transition time of the waveform pulses.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1 is a high-level diagram showing the components of a data-processing system.

FIG. 2 is a high-level diagram showing a ferroelectric device.

FIG. 3 is a high-level diagram showing a waveform having a ramp function.

FIG. 4 is a high-level diagram showing a waveform having a step function.

FIG. 5 is a high-level diagram showing a device including a resistive element in series with a ferroelectric element.

FIG. 6 is a high-level diagram showing a device including a temperature control unit operatively coupled to a ferroelectric element.

FIG. 7 is a diagram illustrating the difference between traditional dielectrics and ferroelectric devices.

FIG. 8 is a chart illustrating the relationships between transition time and device lifetime; and temperature and lifetime.

The attached drawings are for purposes of illustration and are not necessarily to scale.

### DETAILED DESCRIPTION

In the following description, some aspects will be described in terms that would ordinarily be implemented as software programs. Those skilled in the art will readily recognize that the equivalent of such software can also be constructed in hardware, firmware, or micro-code. Because data-manipulation algorithms and systems are well known, the present description will be directed in particular to algorithms and systems forming part of, or cooperating more directly with, systems and methods described herein. Other aspects of such algorithms and systems, and hardware or software for producing and otherwise processing the signals involved therewith, not specifically shown or described herein, are selected from such systems, algorithms, components, and elements known in the art. Given the systems and methods as described herein, software not specifically shown, suggested, or described herein that is useful for implementation of any aspect is conventional and within the ordinary skill in such arts.

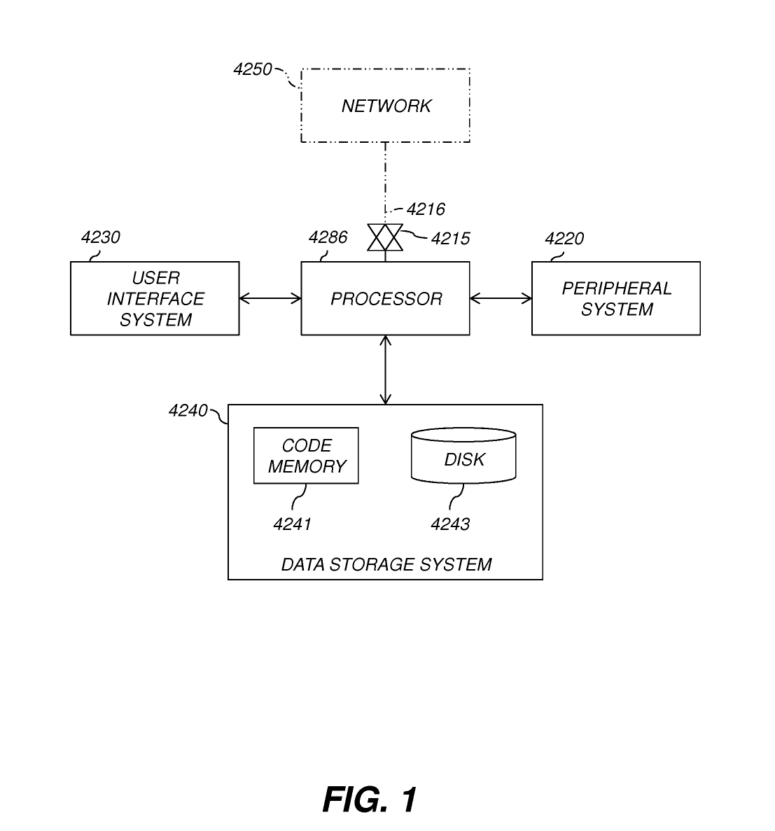

FIG. 1 is a high-level diagram showing the components of an exemplary data-processing system for analyzing data, operating FeRAM elements, controlling temperature control units (FIG. T6) and performing other analyses and methods described herein, and related components. The system includes a processor 4286, a peripheral system 4220, a user interface system 4230, and a data storage system 4240. The peripheral system 4220, the user interface system 4230 and the data storage system 4240 are communicatively connected to the processor 4286. Processor 4286 can be communicatively connected to network 4250 (shown in phantom), e.g., the Internet or an X.425 network, as discussed below. The drive and control circuit shown, e.g., in FIG. 1 can include one or more of systems 4286, 4220, 4230, 4240, and can connect to one or more network(s) 4250. Processor 4286, and other processing devices described herein, can each include one or more microprocessors, microcontrollers, field-programmable gate arrays (FPGAs), application-specific integrated circuits (ASICs), programmable logic devices (PLDs), programmable logic arrays (PLAs), programmable array logic devices (PALs), or digital signal processors (DSPs). Processor 4286 can be a CPU or memory controller.

Processor 4286 can implement processes of various aspects described herein. Processor 4286 can be or include one or more device(s) for automatically operating on data, e.g., a central processing unit (CPU), microcontroller (MCU), desktop computer, laptop computer, mainframe computer, personal digital assistant, digital camera, cellular phone, smartphone, or any other device for processing data, managing data, or handling data, whether implemented with electrical, magnetic, optical, biological components, or otherwise. Processor 4286 can include Harvard-architecture components, modified-Harvard-architecture components, or Von-Neumann-architecture components.

The phrase “communicatively connected” includes any type of connection, wired or wireless, for communicating data between devices or processors. These devices or processors can be located in physical proximity or not. For example, subsystems such as peripheral system 4220, user interface system 4230, and data storage system 4240 are shown separately from the data processing system 4286 but can be stored completely or partially within the data processing system 4286.

The peripheral system 4220 can include one or more devices configured to provide digital content records to the processor 4286. For example, the peripheral system 4220 can include digital still cameras, digital video cameras, cellular phones, or other data processors. The processor 4286, upon receipt of digital content records from a device in the peripheral system 4220, can store such digital content records in the data storage system 4240.

The user interface system 4230 can include a mouse, a keyboard, another computer (connected, e.g., via a network or a null-modem cable), or any device or combination of devices from which data is input to the processor 4286. The user interface system 4230 also can include a display device, a processor-accessible memory, or any device or combination of devices to which data is output by the processor 4286. The user interface system 4230 and the data storage system 4240 can share a processor-accessible memory.

In various aspects, processor 4286 includes or is connected to communication interface 4215 that is coupled via network link 4216 (shown in phantom) to network 4250. For example, communication interface 4215 can include an integrated services digital network (ISDN) terminal adapter or a modem to communicate data via a telephone line; a network interface to communicate data via a local-area network (LAN), e.g., an Ethernet LAN, or wide-area network (WAN); or a radio to communicate data via a wireless link, e.g., WiFi or GSM. Communication interface 4215 sends and receives electrical, electromagnetic or optical signals that carry digital or analog data streams representing various types of information across network link 4216 to network 4250. Network link 4216 can be connected to network 4250 via a switch, gateway, hub, router, or other networking device.

Processor 4286 can send messages and receive data, including program code, through network 4250, network link 4216 and communication interface 4215. For example, a server can store requested code for an application program (e.g., a JAVA applet) on a tangible non-volatile computer-readable storage medium to which it is connected. The server can retrieve the code from the medium and transmit it through network 4250 to communication interface 4215. The received code can be executed by processor 4286 as it is received, or stored in data storage system 4240 for later execution.

Data storage system 4240 can include or be communicatively connected with one or more processor-accessible memories configured to store information. The memories can be, e.g., within a chassis or as parts of a distributed system. The phrase “processor-accessible memory” is intended to include any data storage device to or from which processor 4286 can transfer data (using appropriate components of peripheral system 4220), whether volatile or nonvolatile; removable or fixed; electronic, magnetic, optical, chemical, mechanical, or otherwise. Exemplary processor-accessible memories include but are not limited to: registers, floppy disks, hard disks, tapes, bar codes, Compact Discs, DVDs, read-only memories (ROM), erasable programmable read-only memories (EPROM, EEPROM, or Flash), and random-access memories (RAMs). One of the processor-accessible memories in the data storage system 4240 can be a tangible non-transitory computer-readable storage medium, i.e., a non-transitory device or article of manufacture that participates in storing instructions that can be provided to processor 4286 for execution.

Data-storage system 4240 can include FeRAM, or can store algorithms for controlling ferroelectric devices.

In an example, data storage system 4240 includes code memory 4241, e.g., a RAM, and disk 4243, e.g., a tangible computer-readable rotational storage device such as a hard drive. Computer program instructions are read into code memory 4241 from disk 4243. Processor 4286 then executes one or more sequences of the computer program instructions loaded into code memory 4241, as a result performing process steps described herein. In this way, processor 4286 carries out a computer implemented process. For example, steps of methods described herein, blocks of the flowchart illustrations or block diagrams herein, and combinations of those, can be implemented by computer program instructions. Code memory 4241 can also store data, or can store only code.

Various aspects described herein may be embodied as systems or methods. Accordingly, various aspects herein may take the form of an entirely hardware aspect, an entirely software aspect (including firmware, resident software, micro-code, etc.), or an aspect combining software and hardware aspects These aspects can all generally be referred to herein as a “service,” “circuit,” “circuitry,” “module,” or “system.”

Furthermore, various aspects herein may be embodied as computer program products including computer readable program code stored on a tangible non-transitory computer readable medium. Such a medium can be manufactured as is conventional for such articles, e.g., by pressing a CD-ROM. The program code includes computer program instructions that can be loaded into processor 4286 (and possibly also other processors), to cause functions, acts, or operational steps of various aspects herein to be performed by the processor 4286 (or other processor). Computer program code for carrying out operations for various aspects described herein may be written in any combination of one or more programming language(s), and can be loaded from disk 4243 into code memory 4241 for execution. The program code may execute, e.g., entirely on processor 4286, partly on processor 4286 and partly on a remote computer connected to network 4250, or entirely on the remote computer.

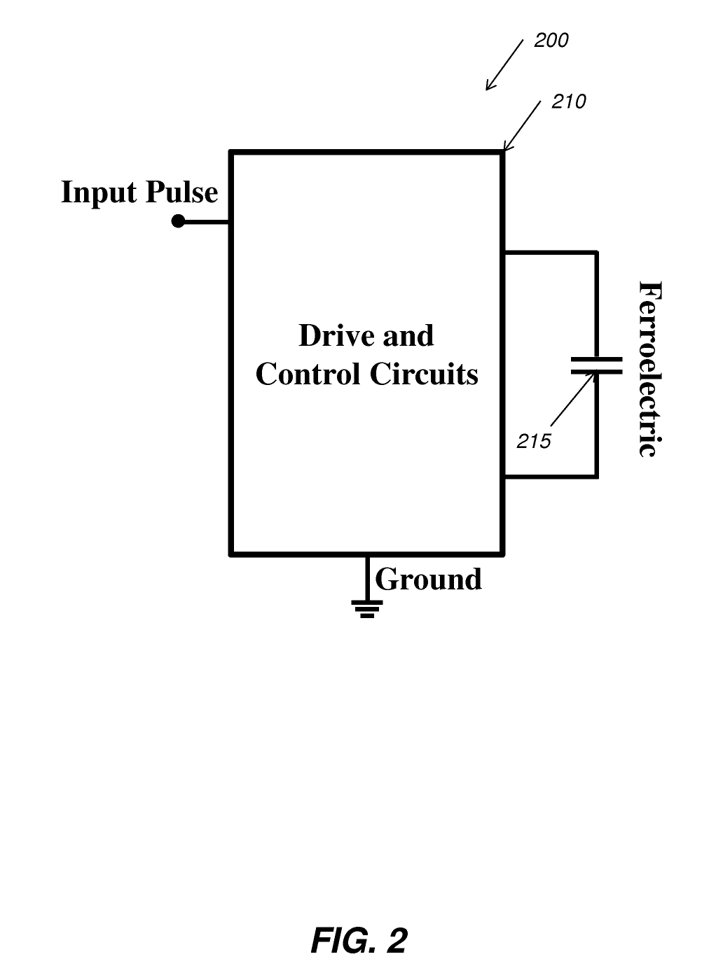

FIG. 2 shows an exemplary ferroelectric system 200 having a drive and control circuit 210 connected to a ferroelectric element 215. The drive and control circuit 210 can include a processor 4286 or other components discussed with reference to FIG. 1. Various switching schemes will now be described which reduce the overshoots of the hot atoms to increase the functional lifetime of the device.

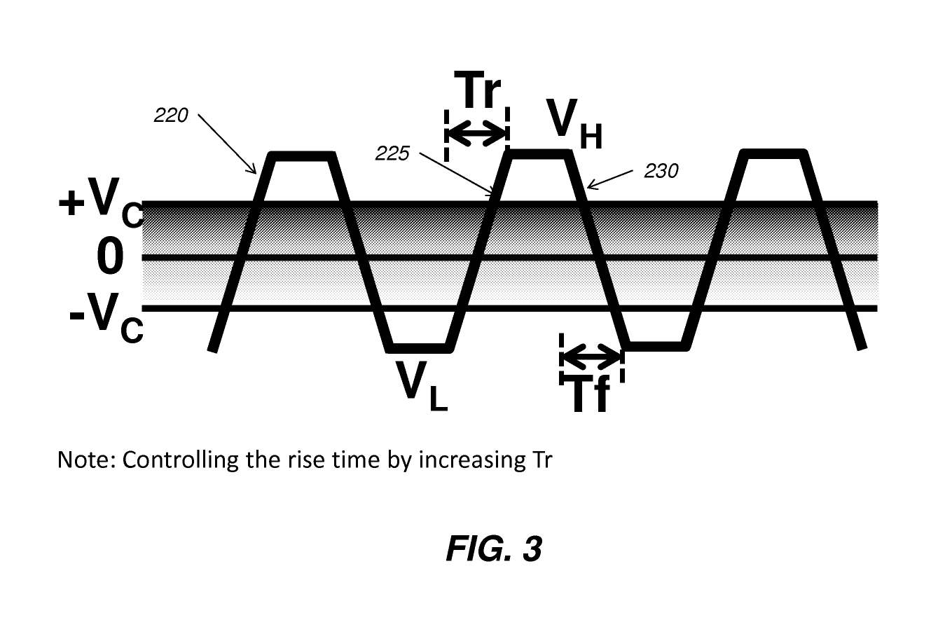

According to one embodiment, the rise time (Tr) of the input pulse 220 may be increased by a predetermined amount to increase the lifetime of the device 215 as shown by the ramp waveform of the rising edge 225 in FIG. 3. Likewise, the fall time (Tf) of the pulse 220 may also be increased as shown by the similar ramp waveform of the falling edge 230, further increasing lifetime. In certain embodiments, the pulses may be symmetrical with respect to the rising edges 225 and falling edges 230 as shown in FIG. 3.

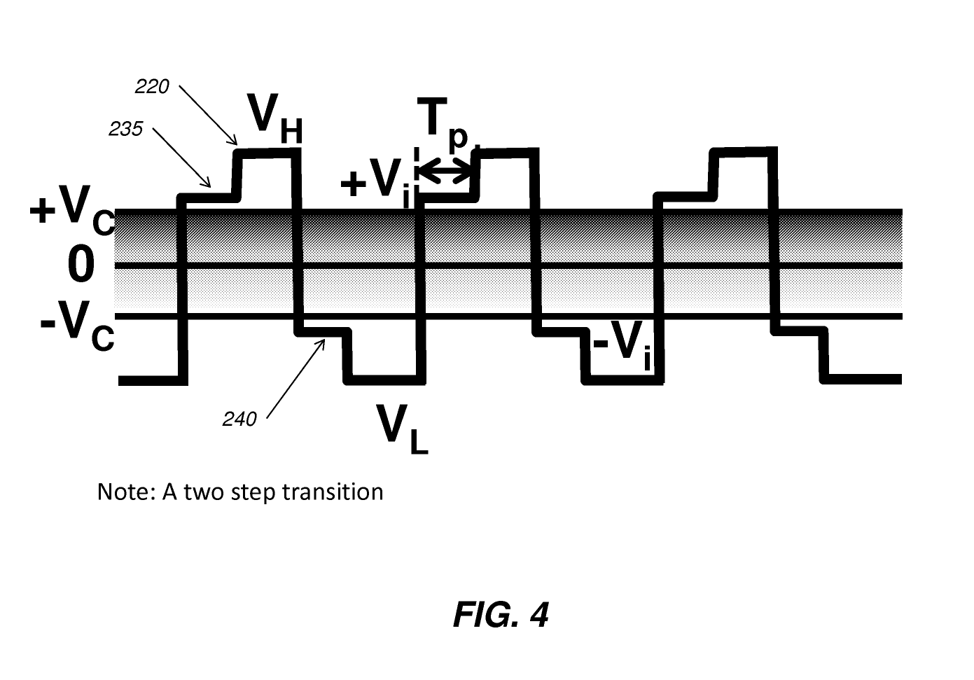

According to another embodiment, a step 235 is applied to the input pulse 220 which interrupts the rise at a selected level as shown in FIG. 4. In various embodiments, the waveforms have a similar step 240 during the falling edge, and the step is at a selected level. In various embodiments, the waveforms are symmetrical, and the steps 235 and 240 are at the same level on the rising edge as on the falling edge with respect to the zero voltage level as shown in FIG. 4. The dwell time at the highest voltage level (V_{H}) or lowest voltage level (V_{L}) can be selected as desired without a significant effect caused by a hot atom on device lifetime. It shall be understood that the waveform pulses have both ramp and step functions incorporated together on the rising or falling edges to increase device lifetime.

In certain embodiments, the step 235 duration time (Tp) can be broken into multiple levels, preferably with all of the levels above +Vc (in the case of the rising edge), or below −Vc (in the case of the falling edge).

Referring again to FIG. 4, showing drive waveforms: changing the waveform after it crosses the coercive voltage +V_{C} (during rising edge) or −V_{C} (during falling edge), and in close temporal proximity to that crossing, can improve lifetime. The specific values of the coercive voltages +V_{C} and −V_{C} can differ for different devices and/or materials. As used herein, the term “coercive voltage” means the voltage at which the ferroelectric device switches from one state to another. For a rising transition (e.g., from 0 to 1 logic state), the coercive voltage is +Vc. For a falling transition (e.g., from 1 to 0 logic state), the coercive voltage is −Vc. Step inputs may be used, which traverses the voltage swing in a plurality of segments having respective slew rates, at least two of the slew rates being different (e.g., high-slew, then 0 slew for a dwell time, then high slew again).

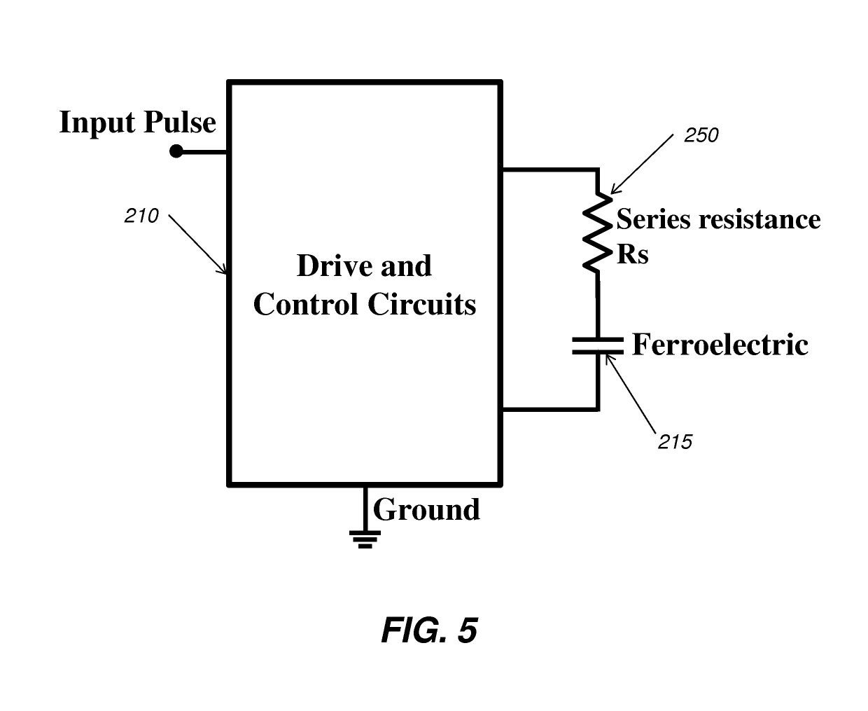

In certain embodiments, a resistance 250 may be connected in series with the ferroelectric device 215 as shown in FIG. 5. The resistance 250 contributes to increased lifetime of the device 215.

Whereas conventional materials can be damaged by the increasing phonon energy as temperature increases, the tested ferroelectric materials actually increase in lifetime with temperature.

At higher temperatures, it is easier to break a molecule from a fluid. E.g., for a given overshoot, higher energy puts the atoms closer to bond-breaking, so it is easier to break bonds using energy from the environment. However, at higher temperatures, the thermal motion of the neighboring atoms also has higher-amplitude. As an atom is moving towards overshoot, it is scattered more by other atoms at higher temperatures than at lower temperatures. This factor reduces the overshoot at higher temperatures.

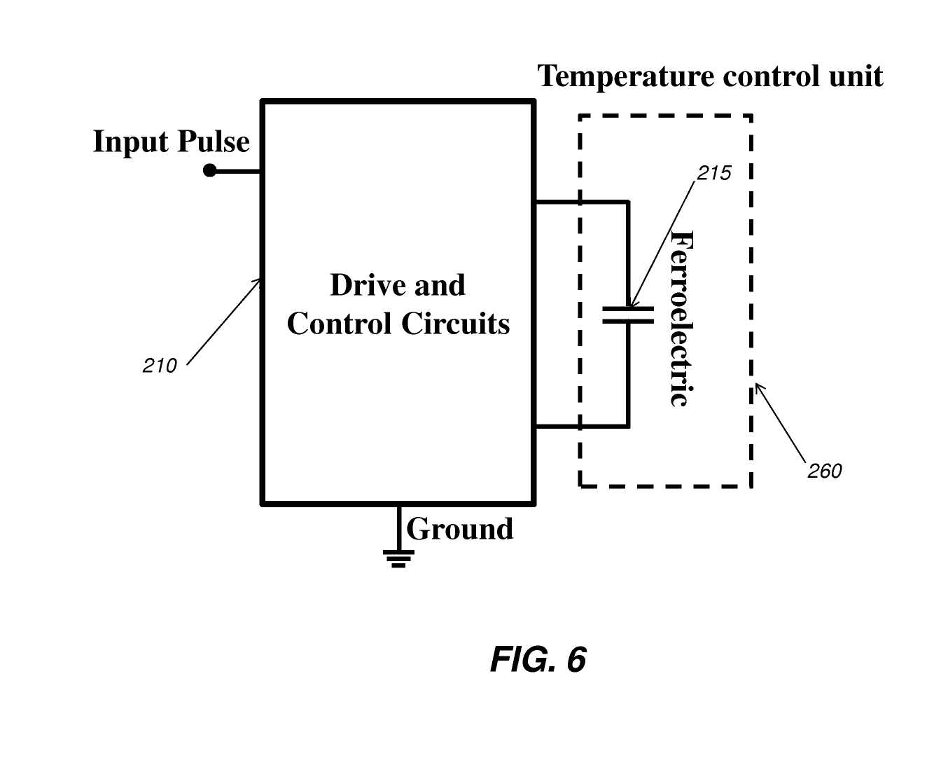

In certain embodiments, a temperature control unit 260 may be operatively connected to the ferroelectric device 215 as shown in FIG. 6 to increase the temperature of the device by a predetermined amount and thus increase lifetime. As one example, the device 215 may be operated at 75° C. as opposed to room temperature.

It shall be understood that waveform (e.g., ramp, step, etc), series resistance, and temperature control can be used independently or together in any combination.

Various techniques described herein increase FeRAM lifetime beyond industry expectations for lifetime. Various techniques increase lifetime so that leakage current on the Iddq pin on a FeRAM chip does not significantly increase before, e.g., 10⁶ or 10⁷ cycles.

Exemplary methods herein including receiving a command to access a FeRAM and, in response, applying a waveform with a ramp or step (as described above) to the FeRAM. Other methods include providing a FeRAM assembly having a resistor in series with the FeRAM element, e.g., manufactured using standard silicon wafer processing. Other methods include receiving a command, controlling the temperature of the FeRAM, and applying a waveform to the FeRAM (with or without a ramp or step). The steps can be performed in any order except when otherwise specified, or when data from an earlier step is used in a later step. Exemplary method(s) herein are not limited to being carried out by the specific components herein.

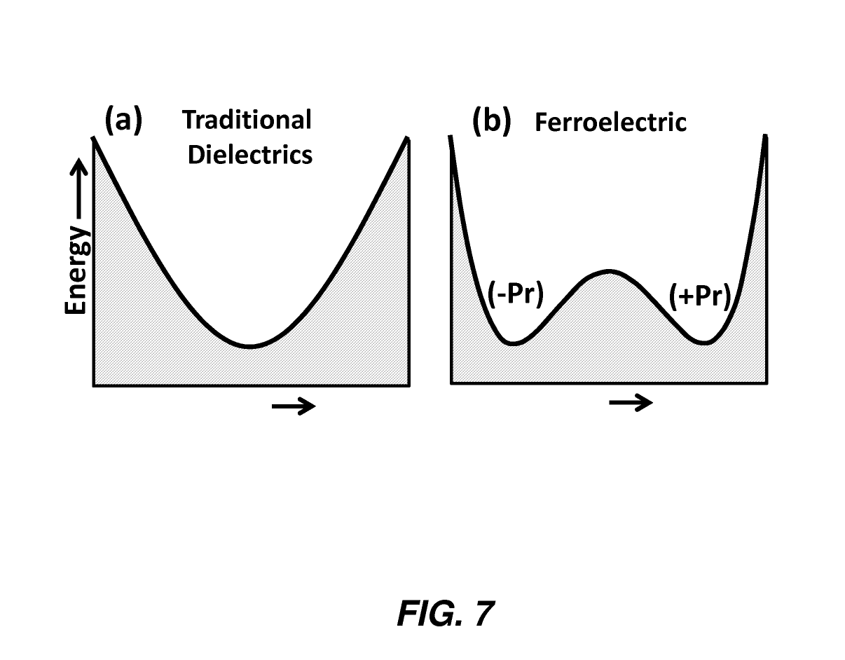

FIG. 7 compares energy levels of traditional dielectrics (a), with only one stable state (bottom of the well), to energy levels of ferroelectrics (b), with two stable states (wells on either side).

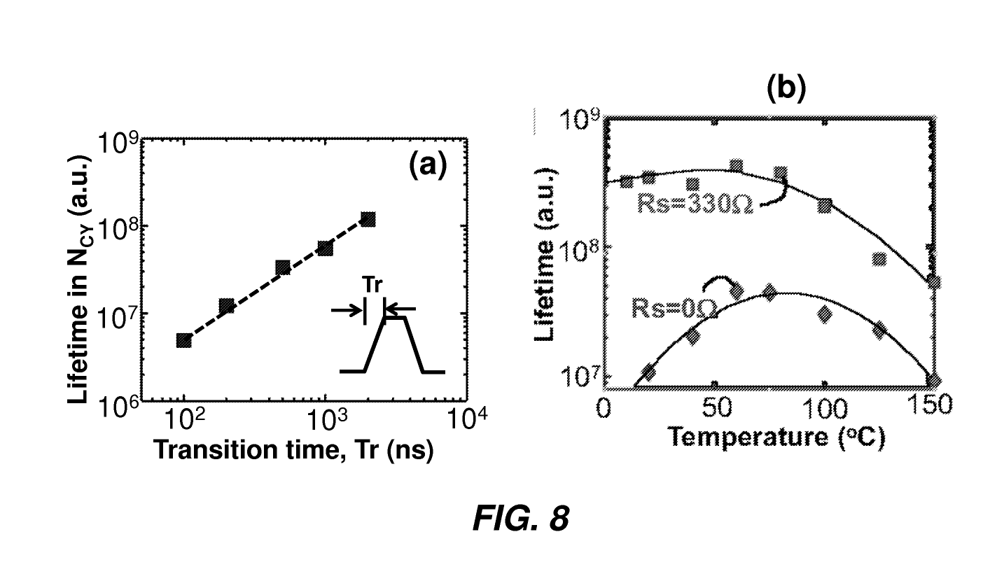

FIG. 8 shows various lifetime effects. In (a), the AC lifetime is shown for different transition (rise) time of the switching pulse. As the rise time increases, the lifetime increases significantly, due to the damping of the switching energy, and correspondingly lesser polarization overshoots. In (b), the lifetime is shown as a function of frequency, with lifetime increasing with temperature to a certain point before decreasing.

In view of the foregoing, various aspects provide improved lifetime of FeRAM elements. A technical effect is to operate a ferroelectric element in a way that increases the lifetime of that element.

The invention is inclusive of combinations of the aspects described herein. References to “a particular aspect” and the like refer to features that are present in at least one aspect of the invention. Separate references to “an aspect” (or “embodiment”) or “particular aspects” or the like do not necessarily refer to the same aspect or aspects; however, such aspects are not mutually exclusive, unless so indicated or as are readily apparent to one of skill in the art. The use of singular or plural in referring to “method” or “methods” and the like is not limiting. The word “or” is used in this disclosure in a non-exclusive sense, unless otherwise explicitly noted.

The invention has been described in detail with particular reference to certain preferred aspects thereof, but it will be understood that variations, combinations, and modifications can be effected by a person of ordinary skill in the art within the spirit and scope of the invention.

1. A method of operating a ferroelectric device, comprising:
receiving a command to operate the ferroelectric device; and
in response to the received command, applying a selected waveform to the ferroelectric device, the selected waveform having a non-zero rise time.

2. The method according to claim 1, wherein the waveform comprises a ramp function.

3. The method according to claim 2, wherein the ramp function is on a rising edge of a pulse of the waveform.

4. The method according to claim 3, wherein the ramp function is on a falling edge of a pulse of the waveform.

5. The method according to claim 1, wherein the waveform comprises a step function.

6. The method according to claim 5, wherein the step function is on a rising edge of a pulse of the waveform.

7. The method according to claim 5, wherein the step function is on a falling edge of a pulse of the waveform.

8. The method according to claim 1, wherein the selected waveform has a selected swing and transverses said swing in more than one step, each step including application of a selected voltage ramp with a selected slew rate, the steps separated in time by dwell times or a region of slew rate.

9. The method according to claim 1, wherein the ferroelectric device comprises FeRAM.

10. A method of operating a ferroelectric device, comprising:
receiving a command to operate the ferroelectric device;
controlling the temperature of the ferroelectric device to increase the temperature of the ferroelectric device above a preselected temperature; and
in response to the received command, applying a selected waveform to the ferroelectric device.

11. The method according to claim 10, wherein the ferroelectric device comprises FeRAM.

12. The method according to claim 10, wherein the waveform comprises a ramp function.

13. The method according to claim 12, wherein the ramp function is on a rising edge of a pulse of the waveform.

14. The method according to claim 12, wherein the ramp function is on a falling edge of a pulse of the waveform.

15. The method according to claim 10, wherein the waveform comprises a step function.

16. The method according to claim 15, wherein the step function is on a rising edge of a pulse of the waveform.

17. The method according to claim 15, wherein the step function is on a falling edge of a pulse of the waveform.

18. A ferroelectric device, comprising:
a ferroelectric element;
a resistive element operatively connected in series with the ferroelectric element; and
a processor configured to apply a waveform across the series combination of the ferroelectric element and the resistive element.

19. The ferroelectric device of claim 18, wherein the ferroelectric element comprises FeRAM.

20. The ferroelectric device of claim 18, wherein the waveform comprises a ramp function.
